(19) United States
(12) Patent Application Publication
(10) Pub. No.: US 2024/0379526 A1
(43) Pub. Date: Nov. 14, 2024

(54) POWER MODULE WITH BALANCED CURRENT FLOW

(71) Applicant: Navitas Semiconductor Limited, Dublin (IE)

(72) Inventor: Oseob Jeon, Seoul (KP)

(73) Assignee: Navitas Semiconductor Limited, Dublin (IE)

(21) Appl. No.: 18/660,832

(22) Filed: May 10, 2024

Related U.S. Application Data
(60) Provisional application No. 63/501,913, filed on May 12, 2023.

(51) Int. Cl. H01L 23/498; H01L 23/00; H01L 25/07; H02M 3/00

(52) U.S. Cl. CPC H01L 23/49838; H01L 24/40; H01L 24/48; H01L 24/73; H01L 24/80; H01L 25/072; H01L 2224/40155; H01L 2224/48139; H01L 2224/48155; H01L 2224/73221; H01L 2224/80801; H01L 2224/8084; H01L 2924/1815; H02M 3/003

(57) ABSTRACT

A power module is designed with balanced current flow for each power switch in parallel so that every power switch has a similar current path length. The power module can include a first plurality of power switches electrically coupled to a first region and a second plurality of power switches electrically coupled to a second region. A first plurality of conductive clips are configured to conduct a first plurality of currents and a second plurality of conductive clips are configured to conduct a second plurality of currents. The power module can include a first lead frame configured to apply positive voltage to the first region, a second lead frame configured to conduct current from the second region and a third lead frame configured to conduct current from the third region.

### CROSS-REFERENCE TO RELATED APPLICATIONS

This application claims priority to U.S. provisional patent application Ser. No. 63/501,913, for “POWER MODULE WITH BALANCED CURRENT FLOW” filed on May 12, 2023, the contents of which are incorporated herein by reference in their entirety for all purposes.

### FIELD

The described embodiments relate generally to power electronics containing one or more semiconductor dies. More particularly, the present embodiments relate to power electronics with semiconductor dies arranged to provide a balanced current flow in each of the semiconductor dies.

### BACKGROUND

Currently there are a wide variety of power modules for power management. The power modules can include multiple semiconductor switches. However, switching performance and the reliability of power modules may be impaired when current imbalances in one or more of the semiconductor switches are present. New electronic packaging architectures are required to provide balanced current flow in power modules.

### SUMMARY

In some embodiments, a power module is disclosed. The power module includes a substrate. The substrate includes an electrically insulative layer. Additionally, the substrate includes a first electrically conductive region disposed on the electrically insulative layer. The substrate further includes a second electrically conductive region disposed on the electrically insulative layer and electrically isolated from the first electrically conductive region. The substrate includes a third electrically conductive region disposed on the electrically insulative layer and electrically isolated from each of the first and the second electrically conductive regions. The power module further includes a plurality of high-side power switches disposed on and electrically coupled to the first electrically conductive region. Additionally, the power module includes a plurality of first connectors electrically coupled between the plurality of high-side power switches and the second electrically conductive region. The power module includes a plurality of low-side power switches disposed on and electrically coupled to the second electrically conductive region. The power module further includes a plurality of second connectors electrically coupled between the plurality of low-side power switches and the third electrically conductive region. A plurality of high-side current paths extending from the first electrically conductive region, through the plurality of high-side power switches, to the second electrically conductive region can be substantially equal in length. A plurality of low-side current paths extending from the third electrically conductive region, through the plurality of low-side power switches, to the second electrically conductive region can be substantially equal in length.

In some embodiments, the second electrically conductive region can define an opening and the third electrically conductive region can be disposed within the opening.

In some embodiments, the third electrically conductive region can have a perimeter that is recessed from the opening to define a gap between the third electrically conductive region and the second electrically conductive region.

In some embodiments, the plurality of second connectors can extend across the gap.

In some embodiments, the first electrically conductive region can be separated from the second electrically conductive region by a space.

In some embodiments, each of the plurality of first connectors can extend across the space.

In some embodiments, a source of each of the plurality of high-side power switches can be connected to a drain of each of the plurality of low-side power switches in a half-bridge configuration.

In some embodiments, each of the plurality of high-side current paths can have a length within 15 percent of each other and each of the plurality of low-side current paths can have a length within 15 percent of each other.

In some embodiments, each of the plurality of high-side power switches and each of the plurality of low-side power switches can be silicon carbide transistors.

In some embodiments, an electronic module is disclosed. The electronic module can include a substrate. The substrate can include an electrically insulative layer. Additionally, the substrate can include an electrically conductive layer formed on the electrically insulative layer. The electrically conductive layer can define first, second, and third electrically conductive regions that are each electrically isolated from each other. The second electrically conductive region can define and opening and the third electrically conductive layer can be disposed within the opening. The electronic module can further include a plurality of high-side power switches disposed on and electrically coupled to the first electrically conductive region. Additionally, the electronic module can include a plurality of first connectors electrically coupled between the plurality of high-side switches and the second electrically conductive region. The electronic module can include a plurality of low-side power switches disposed on and electrically coupled to the second electrically conductive region. Additionally, the electronic module can include a plurality of second connectors electrically coupled between the plurality of low-side power switches and the third electrically conductive region.

In some embodiments, a plurality of high-side current paths extending from the first electrically conductive region, through the plurality of high-side power switches, to the second electrically conductive region can be substantially equal in length.

In some embodiments, a plurality of low-side current paths extending from the third electrically conductive region, through the plurality of low-side power switches, to the second electrically conductive region can be substantially equal in length.

In some embodiments, the third electrically conductive region of the electrically conductive layer can have a perimeter that is recessed from the opening to define a gap between the third electrically conductive region and the second electrically conductive region.

In some embodiments, the plurality of second connectors of the electronic module can extend across the gap.

In some embodiments, the first electrically conductive region of the electronic module can be separated from the second electrically conductive region by a space.

In some embodiments, each of the plurality of first connectors of the electronic module can extend across the space.

In some embodiments, a source of each of the plurality of high-side power switches of the electronic module can be connected to a drain of each of the plurality of low-side power switches in a half-bridge configuration.

In some embodiments, a method is disclosed. The method can include forming an insulative layer of a substrate. Additionally, the method can include forming first, second, and third electrically conducting regions on a top surface of the substrate. Each of the first, second, and third electrically conductive regions can be electrically insulated from each other. The second electrically conductive region can define an opening. The third electrically conductive region can be disposed within the opening. Additionally, the method can include attaching a plurality of high-side power switches to the first electrically conductive region. The method can further involve electrically coupling a plurality of first connectors between the plurality of high-side switches and the second electrically conductive region. The method can include electrically coupling a plurality of low-side power switches to the second electrically conductive region. Additionally, the method can include electrically coupling a plurality of second connectors between the plurality of low-side switches and the third electrically conductive region.

In some embodiments, the method can involve a plurality of high-side current paths extending from the first electrically conductive region, through the plurality of high-side power switches, to the second electrically conductive region that are substantially equal in length.

In some embodiments, the method can involve a plurality of low-side current paths extending from the third electrically conductive region, through the plurality of low-side power switches, to the second electrically conductive region that are substantially equal in length.

### BRIEF DESCRIPTION OF THE DRAWINGS

FIG. 1 is an assembly drawing of a half-bridge power module including four high-side power switches in parallel with four low-side power switches in accordance with embodiments disclosed herein;

FIG. 2 is an assembly drawing of a lead frame for the power module illustrated in FIG. 1;

FIG. 3 is an assembly drawing of the power module illustrated in FIG. 1 with the lead frame illustrated in FIG. 2, attached;

FIG. 4 is an assembly drawing side view of the power module illustrated in FIGS. 1-3;

FIG. 5 is a flow chart of a fabrication process that can be used to make a power module in accordance with embodiments disclosed herein;

FIGS. 6A-6C are assembly drawings of a standardized power module in accordance with embodiments disclosed herein; and

FIGS. 7A-7B are assembly drawings of an power module depicting current paths in two modes of operation in accordance with embodiments disclosed herein.

### DETAILED DESCRIPTION

In some embodiments a high-power DC to DC power conversion module includes a plurality of parallel connected high-side power switches and a plurality of parallel connected low-side power switches that are arranged in a half-bridge configuration. The power switches are attached to a thermally conductive substrate that provides electrical paths to the power switches as well as electrical isolation between the high-side and low-side power switches. Metal clips are used to provide electrical connections between the top surfaces of the power switches and the substrate. The electrical paths and the metal clips are designed to provide balanced current flow through each parallel connected power switch so each power switch has a similar current flow and current path length. Balanced current flow can reduced current crowding in the power switches which can result in increased electrical losses and decreased reliability.

A leadframe assembly forms the power input, ground and signal connections between the substrate and the exterior of the module. The ground lead of the leadframe assembly is positioned over the power input region of the power switches and between the power input leads of the leadframe to minimize stray inductance. The module is encapsulated in a dielectric molding material to protect the power switches and to retain the components in place. A bottom surface of the substrate is exposed so it can be directly coupled to a heatsink to efficiently remove heat from the power switches.

The module has input/output pins on each of four sides of the module such that the pins for power are accessed from the front and the rear sides while the pin outs for signals (I/O) are accessed from the adjacent sides such as the left and the right. This enables optimal use of the substrate area in a given footprint and provides the most compact module size for the lowest possible package cost. In some embodiments, the power switches are silicon carbide (SiC) however in other embodiments they may be silicon, gallium nitride (GaN), or other suitable semiconductor switch.

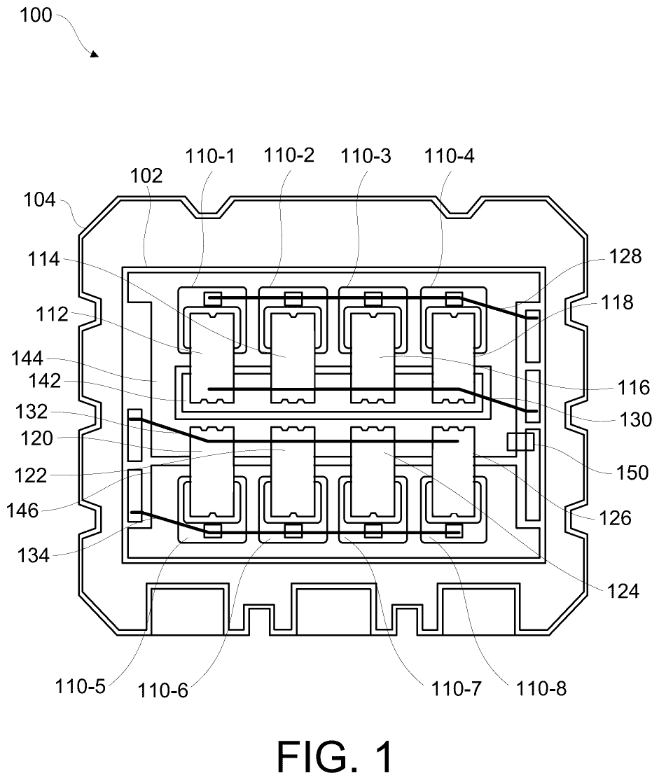

FIG. 1 is a semi-transparent plan view of an example power module 100, according to embodiments of the disclosure. As shown in FIG. 1, power module 100 includes a substrate 102 in a molded case 104. In FIG. 1 some components (e.g., leadframes) are removed for clarity and will be discussed in subsequent figures. Power switches 110 are soldered (or sintered) to the substrate 102. In some embodiments the power switches 110 are field effect transistors (FET) s and they are soldered to the substrate 102 electrically coupling their drains to the substrate. Four low-side power switches 110-1, 110-2, 110-3 and 110-4 are connected in parallel with drain terminals soldered to substrate region 144. While four low-side power switches are shown in FIG. 1, the power module 100 can include any number of low-side power switches, including a single low-side power switch. Four high-side power switches 110-5, 110-6, 110-7, and 110-8 are connected in parallel with drain terminals soldered to substrate region 146. While four high-side power switches are shown in FIG. 1, the power module 100 can include any number of high-side power switches, including a single high-side power switch. The substrate regions 144 and 146 are electrically conductive and are electrically isolated from each other. In some embodiments, substrate 102 can be a direct-bonded copper, insulated metal substrate, or other suitable high thermal conductivity substrate.

One end of a conductive clip 112 is soldered to the top (source) of power switch 110-1 and the other end of conductive clip 112 is soldered to substrate region 142. One end of a conductive clip 114 is soldered to the top of power switch 110-2 and the other end of conductive clip 114 is soldered to substrate region 142. One end of a conductive clip 116 is soldered to the top of power switch 110-3 and the other end of conductive clip 116 is soldered to substrate region 142. One end of a conductive clip 118 is soldered to the top of power switch 110-4 and the other end of conductive clip 118 is soldered to substrate region 142.

One end of a conductive clip 120 is soldered to the top (source) of power switch 110-5 and the other end of conductive clip 120 is soldered to substrate region 144 (switch node). One end of a conductive clip 122 is soldered to the top (source) of power switch 110-6 and the other end of conductive clip 122 is soldered to substrate region 144. One end of a conductive clip 124 is soldered to the top (source) of power switch 110-7 and the other end of conductive clip 124 is soldered to substrate region 144. One end of a conductive clip 126 is soldered to the top (source) of power switch 110-8 and the other end of conductive clip 126 is soldered to substrate region 144.

Clips 112, 114, 116, 118 are all a similar length so that the current paths for current entering and leaving the low-side power switches are equal in length. Clips 120, 122 124 and 126 are all a similar length so that the current paths for current entering and leaving the high-side power switches are equal in length (discussed in more detail below). A sense conductors 130 is used as Kelvin sense wires for power switches 110-1 to 110-4 and a gate conductor 128 is used to operate the gates of the power switches. Sense conductor 132 is used as Kelvin sense wires for switches 110-5 through 110-8 and a gate conductor 134 is used to operate the gates of the power switches. In some embodiments the clips are first attached and the sense wires are subsequently attached. A negative thermal coefficient (NTC) thermal sensor 150 is attached to substrate region 144.

In some embodiments the power module 100 is configured in a half bridge configuration, however other suitable electrical configurations can be used. The input voltage DC (+) is electrically coupled to the drains of high-side power switches 110-5 through 110-8 which are all connected in parallel. The sources of high-side power switches 110-5 through 110-9 are coupled with the drains of low-side power switches 110-1 through 110-4 to form the switch node 144. The sources of low-side switches 110-1 through 110-4 are coupled to ground DC (−) and are all coupled in parallel.

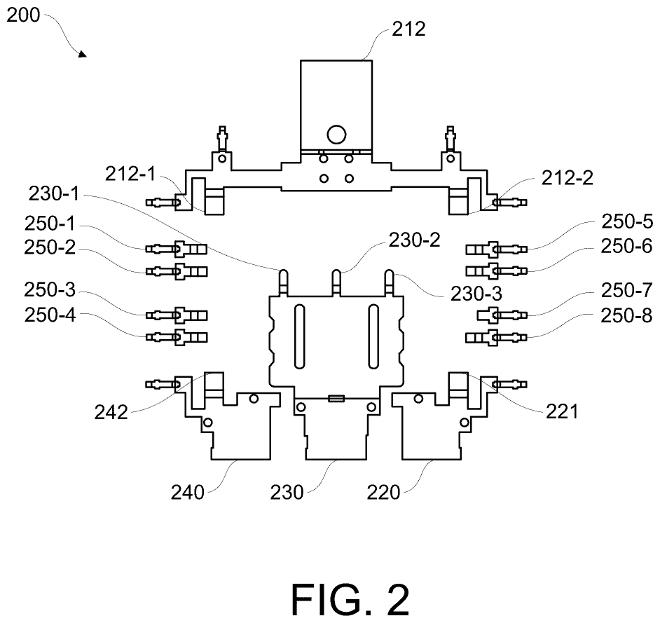

FIG. 2 is a plan view of a lead frame 200 that can form a portion of module 100, shown in FIG. 1. The lead frame connects the module to DC (+) voltage using a right plus power lead 220 and a left plus power lead 240. Right plus power lead 220 includes tab 221 that is connected to the substrate region 146 (see FIG. 1). Left plus power lead 240 includes tab 242 that is connected to the substrate region 146. DC (−) is connected to substrate region 142 (see FIG. 1) using the negative power lead 230. Negative power lead 230 has three negative power lead tabs 230-1, 230-2 and 230-3 that connect to the substrate region 142 (see FIG. 1). Current in the DC (+) direction, through the plus power leads 220, 240 is in the opposite direction of the DC (−) current direction through the negative power lead 230. The two current paths are in close proximity reducing the parasitic/stray inductance. Reducing parasitic inductance improves the switching characteristics. Output lead 212 is connected to the substrate region 144. The output lead 212 is connected to the substrate using tabs 212-1 and 212-2. Tabs 250-1 through 250-8 can form input/output signal connections to module 100.

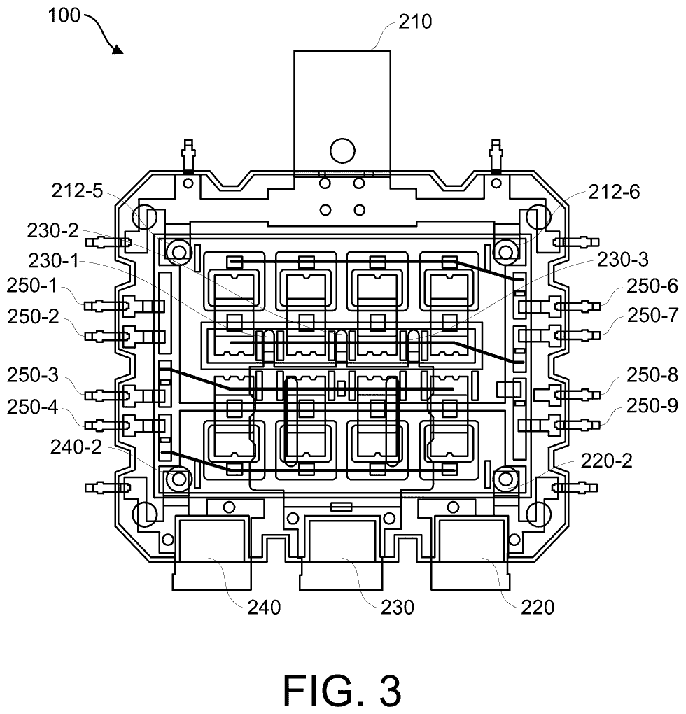

FIG. 3 is a semi-transparent plan view of power module 100 with leadframe 200 attached. With so many elements depicted in FIG. 3, for simplicity, some elements that were numbered and discussed in FIG. 1 are not numbered in FIG. 3. This description of FIG. 3 refers to element numbers defined in the description in FIG. 1. The assembly drawing shows the plus power connections 240-2 and 220-2 connected to the substrate region 146. The negative power lead tabs 230-1, 230-2 and 230-3 are connected to the substrate region 142. The output lead tabs 212-5 and 212-6 are connected to substrate region 144. Kelvin connections are shown and connected to connectors 250-6 and 250-7 along with 250-3 and 250-4. The NTC thermal sensor 150 is connected to 250-9.

Tracing the current flow through the power module 100: a positive voltage supply drives current from the positive voltage supply into substrate region 146 connected to the drains of devices 110-5, 110-6, 110-7 and 110-18. The current path originates from two positive voltage inputs (e.g., right plus power lead 221 and left plus power lead 242) to drains of devices 110-5, 110-6, 110-7 and 110-8. All current paths can be of equal length or the same distance. Equal distances mean that the parasitic impedance is the same for all paths. Equal impedance means the current will be the same. As defined herein, the same distance or substantially the same distance means a length of each current path is within 0.1 mm, within 0.5 mm, within 1 mm or within 2 mm of a length of the other current paths. Current passes through the devices 110-5, 110-6, 110-7 and 110-8 and the source of each device is tied to substrate 144 through conductive clips 120, 122, 124 and 126. Each of the conductive clips 120, 122, 124, and 126 are the same length making the current through each device the same. Substrate region 144 conducts the current to the drains of power devices 110-1, 110-2, 110-3 and 110-4. The current flows through devices 110-1, 110-2, 110-3 and 110-4 and is conducted through conductive clips 112, 114, 116 and 118 and are electrically coupled to substrate region 142. The current path through the power devices and the conductor clips are all of equal length so that the parasitic impedance will again be equal. In this manner the current between devices will all be equal. In other words, a plurality of switches connected with a plurality of clips yields a plurality of currents whose physical current paths (or plurality of current paths) are equal. Substrate region 142 is connected to negative power connections 230-1, 230-2, and 230-3. A return current to the negative supply can pass over current originating from the positive supply, cancelling some magnetic characteristics of the interconnection yielding a lower parasitic inductance.

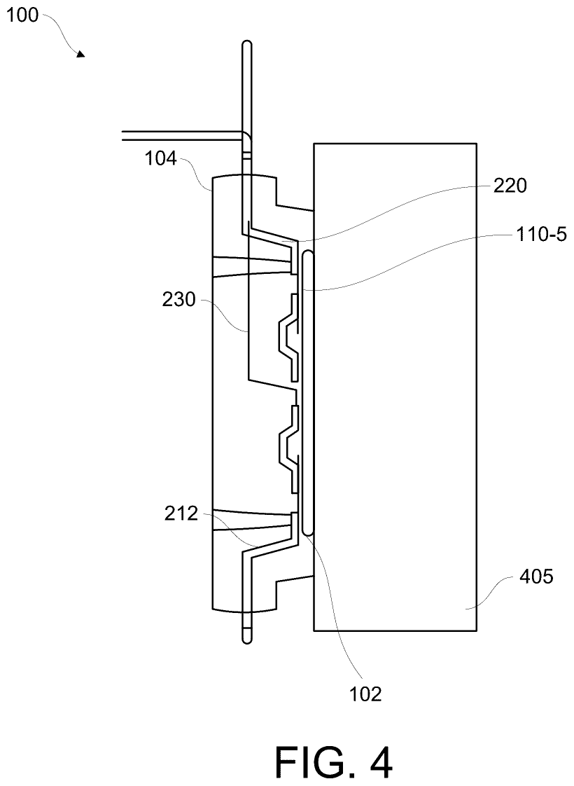

FIG. 4 is a semi-transparent side view of power module 100. As shown in FIG. 4 dielectric mold material 104 partially encapsulates substrate 102 such that a bottom surface of the substrate is exposed. The negative power lead 230 is shown coupled with the substrate 102 and is shown as extending over high-side power switches (e.g., 110-5). The right plus power lead 220 is also shown connected to the substrate 102. The output lead 212 is shown attached to the substrate 102.

The module 100 is shown as attached to a heat sink 405. The module 100 is thermally coupled to heat sink 405 at a bottom surface of substrate 102. The substrate 102 can be thermally coupled to the heat sink 405 using solder, a sintered silver connection, a thermal interface material or other suitable coupling material.

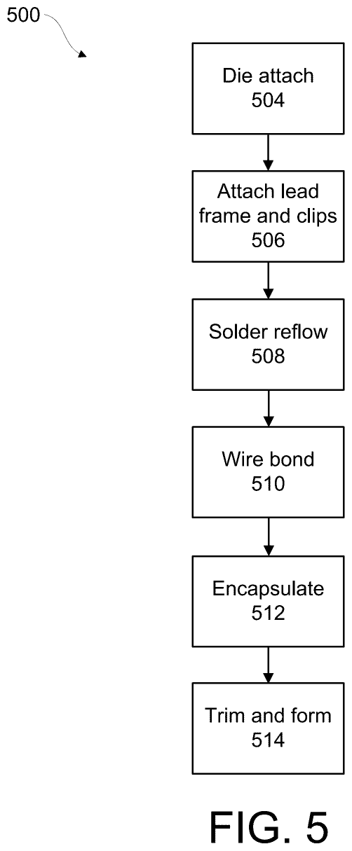

FIG. 5 is a flow chart of an example fabrication process 500 that may be used to make module 100, according to embodiments of the disclosure. The process starts with die attach 504 when the switches are attached to the substrate via solder, sintering or other suitable process. In step 506 a solder dispensing process is performed, then the leadframe and the clips are placed in position. In step 508 the solder is reflowed to solder the clips and leadframe in place. In step 510 the module is wire bonded to form the Kelvin connections. In step 512 the module is encapsulated with a dielectric mold material. In step 514 the leads are trimmed and formed. Various other processes may be performed including cleaning and the like. For example, in some embodiments the clips and/or leadframe may be welded, brazed, glued or attached using a process other than solder.

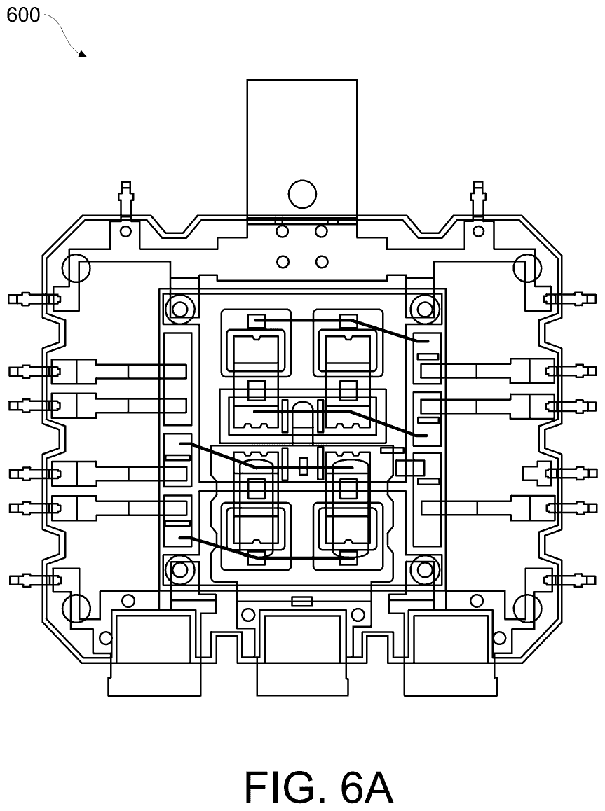

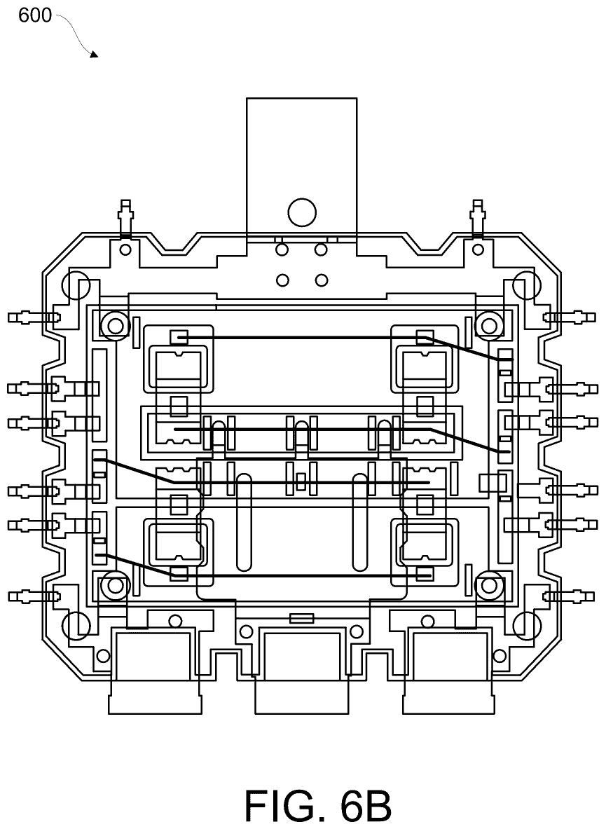

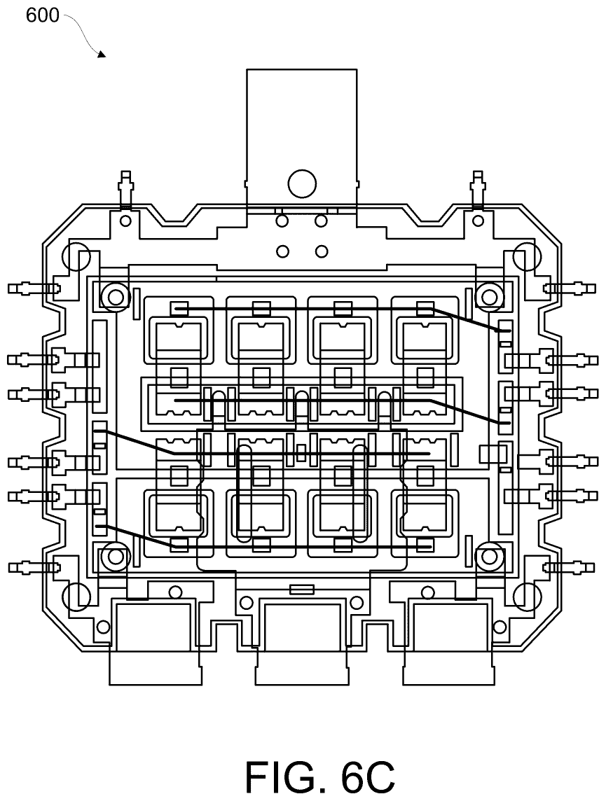

FIGS. 6A-6C illustrate a standardized power module 600 that can have varied configurations to minimize cost and enable multiple products. Power module 600 may be or include any of the components, features, or characteristics of any of the power modules previously described. FIG. 6A shows a standardized power module with a reduced size substrate and two high-side and two low-side power switches. This can be a reduced current and reduced cost module. FIG. 6B shows a standardized power module with a full-size substrate and two high-side and two low-side power switches. The standardized module in FIG. 6B may use identical leadframes and encapsulation equipment as the module in FIG. 6A, but may have improved thermal performance due to the larger substrate. FIG. 6C shows a standardized power module with a full-size substrate and four high-side and four low-side power switches. The module in FIG. 6C may use identical leadframes and encapsulation equipment as the modules in FIGS. 6A and 6B, but may have improved current capability due to the increased number of power switches. Other variants are within the scope of this disclosure.

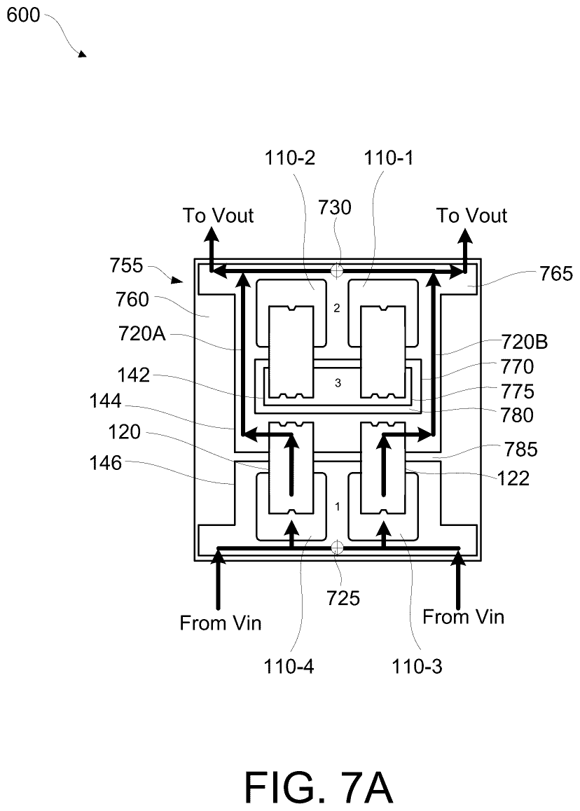

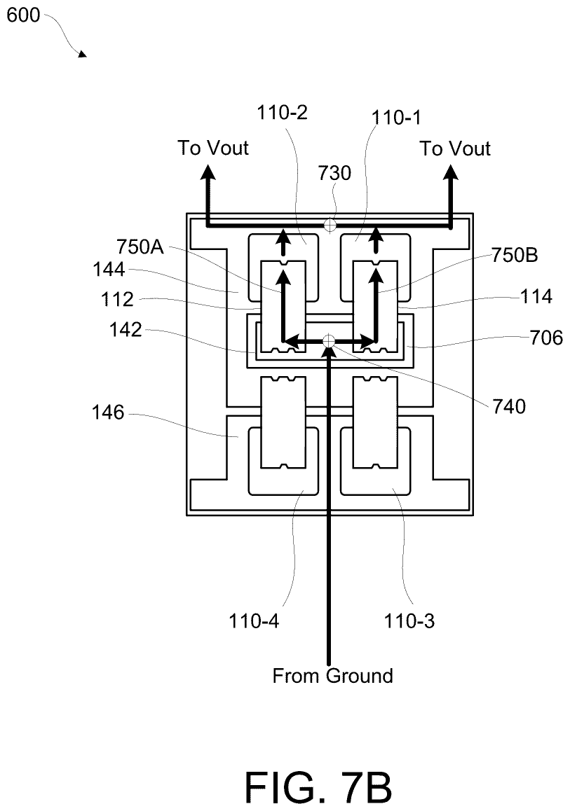

FIGS. 7A-7B are simplified drawings depicting current paths in multiple modes of operation of a power module 600. FIG. 7A depicts the power module 600 operating in a first “high-side” mode of operation. The power module 600 can include a substrate 755 in a molded case. In FIG. 7A, some components (e.g., leadframes) are removed for clarity and are discussed in previous figures. Substrate 755 may include an electrically insulative layer 760 made from a ceramic, polymer or other electrically insulative material. An electrically conductive layer 765 can be formed on the electrically insulative layer 755 and defining first, second and third electrically conductive regions, 146, 144, 142, respectively, that are each electrically insulated from each other. The second electrically insulative region 144 defines an opening 770 and the third electrically conductive region 142 is disposed within the opening.

The third electrically conductive region 142 has a perimeter 775 that is recessed from the opening 770 to define a gap 780 between the third electrically conductive region and the second electrically conductive region 144. 5. The first electrically conductive region 146 is separated from the second electrically conductive region 144 by a space 785.

Power switches 110 are soldered (or sintered) to the substrate. In some embodiments, the power switches are soldered to the substrate by electrically coupling drains to the substrate. Two low-side power switches 110-1 and 110-2 are connected in parallel with drain terminals soldered to substrate region 144. While two low-side power switches are shown in FIG. 7A, the power module 600 can include any number of low-side power switches, including a single low-side power switch. Two high-side power switches 110-3 and 110-4 are connected in parallel with drain terminals attached to substrate region 146. While two high-side power switches are shown in FIG. 7A, the power module can include any number of high-side power switches, including a single high-side power switch. The substrate regions 144 and 146 are electrically conductive and are electrically isolated from each other by an insulative substrate that can be made from a ceramic. In some embodiments, the substrate can be a direct-bonded copper, insulated metal substrate, or other suitable high thermal conductivity substrate. In the first mode of operation, the two high-side power switches 110-3 and 110-4 can be in an ‘ON’ state, while the two low-side power switches 110-1 and 110-2 can be in an ‘OFF’ state.

One end of a connector 120 can be soldered to a top (source) of power switch 110-4 and a second end of the connector 120 can be soldered to substrate region 144 (switch node). One end of a connector 122 can be soldered to a top (source) of power switch 110-3 and a second end of the connector 122 can be soldered to substrate region 144. Each of the connectors 120, 122 can be conductive clips. The connectors 120, 122 can all be a same or similar length so that current paths for current entering and leaving the high-side power switches 110-3, 110-4 are equal in length. In some embodiments connectors can be fabricated from a conductive metal such as copper or a copper-based alloy.

In some embodiments, the power module 600 is configured in a half bridge configuration, however other suitable electrical configurations can be used. An input DC voltage (e.g., via a positive terminal such as positive terminals 220, 240 shown in FIG. 2) can be electrically coupled to the drains of the high-side power switches 110-3, 110-4, which can be connected in parallel. The sources of the high-side power switches 110-3, 110-4 can be electrically coupled to the drains of low-side power switches 110-2, 110-1 to form the switch node 144. The sources of the low-side power switches 110-2, 110-1 can be coupled to ground (e.g., via a negative terminal, such as ground terminal 230 shown in FIG. 2) and can be coupled in parallel.

When the power module 600 is in the first “high-side” mode of operation, first and second parallel current paths 720A, 720B, respectively, can form through the power module 600. Each of the first and second current paths, 720A, 720B, respectively, can originate from a positive terminal (e.g., positive terminal 220 or 240 shown in FIG. 2) and can terminate at an output terminal (e.g., output terminal 212 shown in FIG. 2). A first path 720A can begin in a bottom left portion of substrate region 146 and can lead to the drain of power switch 110-4. The first path 720A can continue from the drain to the source of power switch 110-4 and across connector 120 into substrate region 144. The first path 720A can continue through the substrate region 144 until the first path terminates in an upper left corner of the substrate region 144, where the substrate region 144 is in electrical contact with the output terminal (e.g., output terminal 212 shown in FIG. 2).

The second path 720B can begin in a bottom right portion of substrate region 146 and can lead to the drain of power switch 110-3. The second path 720B can continue from the drain to the source of power switch 110-3 and across connector 122 into substrate region 144. The second path 720B can continue through the substrate region 144 until the first path terminates in an upper right corner of the substrate region 144, where the substrate region 144 is in electrical contact with the output terminal (e.g., output terminal 212 shown in FIG. 2). As shown in FIG. 7A, the first path 720A and the second path 720B can be equal length and can contribute to a current balance in the power module 600 during the first mode of operation. More specifically, first and second paths 720A, 720B, respectively, may have path lengths that are substantially identical between a common Vin location 725 and a common Vout location 730. As defined herein, substantially identical path lengths are within 15%, within 10%, within 7%, within 5% or within 2% of each other. As described herein, the substantially identical, or equal, path lengths may enable equal current sharing and equal switching performance between the semiconductor switches resulting in reduced electrical losses and improved reliability.

The drawing of FIG. 7B depicts the power module 600 operating in a second “low-side” mode of operation. Two low-side power switches 110-1 and 110-2 are connected in parallel with drain terminals soldered to substrate region 144. While two low-side power switches are shown in FIG. 7B, the power module 600 can include any number of low-side power switches, including a single low-side power switch. The substrate regions 144 and 146 are electrically conductive and are electrically isolated from each other. In the second “low-side” mode of operation, the two high-side power switches 110-3 and 110-4 can be in an ‘OFF’ state, while the two low-side power switches 110-1 and 110-2 can be in an ‘ON’ state.

One end of a connector 112 can be soldered to a top (source) of power switch 110-2 and a second end of the connector 112 can be soldered to substrate region 142. One end of a connector 114 can be soldered to a top (source) of power switch 110-1 and a second end of the connector 114 can be soldered to substrate region 142. Each of the connectors 112, 114 can be conductive clips. The connectors 112, 114 can all be a same or similar length so that current paths for current entering and leaving the low-side power switches 110-1, 110-2 are equal in length.

When the power module 600 is in the second “low-side” mode of operation, third and fourth current paths 750A, 750B, respectively, can form through the power module 600. Each of the two paths can originate from an output terminal (e.g., output terminal 212 shown in FIG. 2) and can terminate at a ground terminal (e.g., negative terminal 230 shown in FIG. 2). The third path 750A can begin at a ground region of substrate (e.g., region 142) go through a connector to a source of switch 110-2 then to a Vin region 144 of the substrate. The fourth path 750B can begin at the ground region of substrate (e.g., region 142) go through a connector so a source of switch 110-1 then to the Vin region 144 of the substrate. As shown in FIG. 7B, the third path 750A and the fourth path 750B can be equal length and can contribute to a current balance in the power module 600 during the second mode of operation. More specifically, third and fourth paths 750A, 750B, respectively, may have path lengths that are substantially identical, or substantially equal, between a common ground location 740 and the common Vout location 730. As defined herein, substantially identical path lengths are within 15%, within 10%, within 7%, within 5% or within 2% of each other.

In some embodiments switches and/or diodes may be fabricated with gallium nitride GaN, silicon carbide SiC, and/or silicon. In various embodiments one or more of the switches may be field-effect switches including but not limited to enhancement mode and depletion mode switches.

One of ordinary skill in the art will appreciate that various features and aspects of the power module with balanced current can be changed, modified and manipulated which are within the scope of this disclosure.

In the foregoing specification, embodiments of the disclosure have been described with reference to numerous specific details that can vary from implementation to implementation. The specification and drawings are, accordingly, to be regarded in an illustrative rather than a restrictive sense. The sole and exclusive indicator of the scope of the disclosure, and what is intended by the applicants to be the scope of the disclosure, is the literal and equivalent scope of the set of claims that issue from this application, in the specific form in which such claims issue, including any subsequent correction. The specific details of particular embodiments can be combined in any suitable manner without departing from the spirit and scope of embodiments of the disclosure.

Additionally, spatially relative terms, such as “bottom or “top” and the like can be used to describe an element and/or feature's relationship to another element(s) and/or feature(s) as, for example, illustrated in the figures. It will be understood that the spatially relative terms are intended to encompass different orientations of the switch in use and/or operation in addition to the orientation depicted in the figures. For example, if the switch in the figures is turned over, elements described as a “bottom” surface can then be oriented “above” other elements or features. The switch can be otherwise oriented (e.g., rotated 90 degrees or at other orientations) and the spatially relative descriptors used herein interpreted accordingly.

Terms “and,” “or,” and “an/or,” as used herein, may include a variety of meanings that also is expected to depend at least in part upon the context in which such terms are used. Typically, “or” if used to associate a list, such as A, B, or C, is intended to mean A, B, and C, here used in the inclusive sense, as well as A, B, or C, here used in the exclusive sense. In addition, the term “one or more” as used herein may be used to describe any feature, structure, or characteristic in the singular or may be used to describe some combination of features, structures, or characteristics. However, it should be noted that this is merely an illustrative example and claimed subject matter is not limited to this example. Furthermore, the term “at least one of” if used to associate a list, such as A, B, or C, can be interpreted to mean any combination of A, B, and/or C, such as A, B, C, AB, AC, BC, AA, AAB, ABC, AABBCCC, etc.

Reference throughout this specification to “one example,” “an example,” “certain examples,” or “exemplary implementation” means that a particular feature, structure, or characteristic described in connection with the feature and/or example may be included in at least one feature and/or example of claimed subject matter. Thus, the appearances of the phrase “in one example,” “an example,” “in certain examples,” “in certain implementations,” or other like phrases in various places throughout this specification are not necessarily all referring to the same feature, example, and/or limitation. Furthermore, the particular features, structures, or characteristics may be combined in one or more examples and/or features.

In the preceding detailed description, numerous specific details have been set forth to provide a thorough understanding of claimed subject matter. However, it will be understood by those skilled in the art that claimed subject matter may be practiced without these specific details. In other instances, methods and apparatuses that would be known by one of ordinary skill have not been described in detail so as not to obscure claimed subject matter. Therefore, it is intended that claimed subject matter not be limited to the particular examples disclosed, but that such claimed subject matter may also include all aspects falling within the scope of appended claims, and equivalents thereof.

What is claimed is:

1. A power module comprising:
a substrate comprising:
an electrically insulative layer;
a first electrically conductive region disposed on the electrically insulative layer;
a second electrically conductive region disposed on the electrically insulative layer and electrically isolated from the first electrically conductive region; and
a third electrically conductive region disposed on the electrically insulative layer and electrically isolated from each of the first and the second electrically conductive regions;
a plurality of high-side power switches disposed on and electrically coupled to the first electrically conductive region;
a plurality of first connectors electrically coupled between the plurality of high-side power switches and the second electrically conductive region;
a plurality of low-side power switches disposed on and electrically coupled to the second electrically conductive region;
a plurality of second connectors electrically coupled between the plurality of low-side power switches and the third electrically conductive region;
wherein a plurality of high-side current paths extending from the first electrically conductive region, through the plurality of high-side power switches, to the second electrically conductive region are substantially equal in length; and
wherein a plurality of low-side current paths extending from the third electrically conductive region, through the plurality of low-side power switches, to the second electrically conductive region are substantially equal in length.

2. The power module of claim 1, wherein the second electrically conductive region defines an opening and wherein the third electrically conductive region is disposed within the opening.

3. The power module of claim 2, wherein the third electrically conductive region has a perimeter that is recessed from the opening to define a gap between the third electrically conductive region and the second electrically conductive region.

4. The power module of claim 3, wherein each of the plurality of second connectors extend across the gap.

5. The power module of claim 1, wherein the first electrically conductive region is separated from the second electrically conductive region by a space.

6. The power module of claim 5, wherein each of the plurality of first connectors extend across the space.

7. The power module of claim 1, wherein a source of each of the plurality of high-side power switches is connected to a drain of each of the plurality of low-side power switches in a half-bridge configuration.

8. The power module of claim 1, wherein each of the plurality of high-side current paths have a length within 15 percent of each other and wherein each of the plurality of low-side current paths have a length within 15 percent of each other.

9. The power module of claim 1, wherein each of the plurality of high-side power switches and each of the plurality of low-side power switches are silicon carbide transistors.

10. An electronic module comprising:
a substrate comprising:
an electrically insulative layer; and
an electrically conductive layer formed on the electrically insulative layer and defining first, second, and third electrically conductive regions that are each electrically insulated from each other, wherein the second electrically insulative region defines an opening, and wherein the third electrically conductive region is disposed within the opening;
a plurality of high-side power switches disposed on and electrically coupled to the first electrically conductive region;
a plurality of first connectors electrically coupled between the plurality of high-side switches and the second electrically conductive region;
a plurality of low-side power switches disposed on and electrically coupled to the second electrically conductive region; and
a plurality of second connectors electrically coupled between the plurality of low-side power switches and the third electrically conductive region.

11. The electronic module of claim 10, wherein a plurality of high-side current paths extending from the first electrically conductive region, through the plurality of high-side power switches, to the second electrically conductive region are substantially equal in length.

12. The electronic module of claim 10, wherein a plurality of low-side current paths extending from the third electrically conductive region, through the plurality of low-side power switches, to the second electrically conductive region are substantially equal in length.

13. The electronic module of claim 10, wherein the third electrically conductive region is defined by a perimeter that is recessed from the opening to define a gap between the third electrically conductive region and the second electrically conductive region.

14. The electronic module of claim 13, wherein each of the plurality of second connectors extend across the gap.

15. The electronic module of claim 10, wherein the first electrically conductive region is separated from the second electrically conductive region by a space.

16. The electronic module of claim 15, wherein each of the plurality of first connectors extend across the space.

17. The electronic module of claim 10, wherein a source of each of the plurality of high-side power switches is connected to a drain of each of the plurality of low-side power switches in a half-bridge configuration.

18. A method of forming an electronic module, the method comprising:
forming an insulative layer of a substrate;
forming first, second, and third electrically conductive regions on a top surface of the substrate, wherein each of the first, second, and third electrically conductive regions are each electrically insulated from each other, wherein the second electrically insulative region defines an opening, and wherein the third electrically conductive region is disposed within the opening;
attaching a plurality of high-side power switches to the first electrically conductive region;
electrically coupling a plurality of first connectors between the plurality of high-side switches and the second electrically conductive region;
electrically coupling a plurality of low-side power switches to the second electrically conductive region; and
electrically coupling a plurality of second connectors between the plurality of low-side switches and the third electrically conductive region.

19. The method of claim 18, wherein a plurality of high-side current paths extending from the first electrically conductive region, through the plurality of high-side power switches, to the second electrically conductive region are substantially equal in length.

20. The method of claim 18, wherein a plurality of low-side current paths extending from the third electrically conductive region, through the plurality of low-side power switches, to the second electrically conductive region are substantially equal in length.
